(19) United States
(12) Patent Application Publication
(10) Pub. No.: US 2019/0355860 A1
(43) Pub. Date: Nov. 21, 2019

(54) SOLAR CELL

(71) Applicant: LG ELECTRONICS INC., Seoul (KR)

(72) Inventors: Hyungseok KIM, Seoul (KR); Kwangsun JI, Seoul (KR); Youngjoo EO, Seoul (KR); Heonmin LEE, Seoul (KR); Choul KIM, Seoul (KR); Hojung SYN, Seoul (KR); Wonseok CHOI, Seoul (KR); Kihoon PARK, Seoul (KR); Junghoon CHOI, Seoul (KR); Hyunjin YANG, Seoul (KR)

(73) Assignee: LG ELECTRONICS INC., Seoul (KR)

(21) Appl. No.: 16/530,701

(22) Filed: Aug. 2, 2019

Related U.S. Application Data
(62) Division of application No. 13/216,922, filed on Aug. 24, 2011.

(30) Foreign Application Priority Data
Aug. 25, 2010 (KR) 10-2010-0082511
Aug. 23, 2011 (KR) 10-2011-0083855

(51) Int. Cl. H01L 31/0747; H01L 31/0216

(52) U.S. Cl. CPC H01L 31/0747; Y02E 10/50; H01L 31/02167

(57) ABSTRACT

A solar cell can include a single crystalline semiconductor substrate; an emitter region positioned on an incident surface of the substrate, forming a p-n junction with the single crystalline semiconductor substrate; a first passivation layer positioned on a rear surface of the substrate and made of an oxide material; a back surface field layer positioned on the first passivation layer and forming a hetero junction with the single crystalline semiconductor substrate; a first electrode electrically connected to the emitter region; and a second electrode electrically connected to the single crystalline semiconductor substrate

### CROSS-REFERENCE TO RELATED APPLICATIONS

This application is a Divisional of co-pending U.S. application Ser. No. 13/216,922 filed on Aug. 24, 2011, which claims priority to and the benefit of Korean Patent Application No. 10-2010-0082511 and No. 10-2011-0083855, filed in the Korean Intellectual Property Office on Aug. 25, 2010 and Aug. 23, 2011, respectively, the entire contents of all these applications are incorporated herein by reference into the present application.

### BACKGROUND OF THE INVENTION

### (a) Field of the Invention

Embodiments of the invention relate to a solar cell.

### (b) Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, electron-hole pairs are generated in the semiconductor parts. The electrons move to the n-type semiconductor part and the holes move to the p-type semiconductor part, and then the electrons and holes are collected by the electrodes connected to the n-type semiconductor part and the p-type semiconductor part, respectively. The electrodes are connected to each other using electric wires to thereby obtain electric power.

### SUMMARY OF THE INVENTION

In one aspect, there is a solar cell including a substrate made of a crystalline semiconductor, an emitter region made of a non-crystalline semiconductor and forming a p-n junction with the substrate, a first passivation region positioned on the substrate and made of an oxide material, a first electrode electrically connected to the emitter region, and a second electrode electrically connected to the substrate.

The solar cell may further include a surface field region made of the non-crystalline semiconductor positioned on the first passivation region, and containing an impurity of a conductive type equal to a conductive type of the substrate, a concentration of the impurity being greater than a concentration of an impurity of the substrate.

The first passivation region may have a thickness of 1 nm to 10 nm.

The first passivation region may have a fixed charge.

The first passivation region may be positioned on an incident of the substrate and the fixed charge of the first passivation region may be a polarity opposite a conductive type of the substrate.

The fixed charge of the first passivation region may have a magnitude of 1×10¹²/cm² to 1×10¹⁵/cm².

When the substrate may be of a p-type, the first passivation region may be made of aluminum oxide, and when the substrate may be of an n-type, the first passivation region may be made of silicon oxide.

The first passivation region may have a thickness of 3 nm to 20 nm.

The solar cell may further include a surface field region of the non-crystalline semiconductor positioned on the first passivation region and more heavily doped with an impurity of a conductive type equal to a conductive type of the substrate than the substrate.

The first passivation region may be made of silicon oxide, aluminum oxide or zinc oxide.

The emitter region may be positioned on a first surface opposite a second surface of the substrate, the second surface being an incident surface of the substrate, on which light is incident.

The solar cell may further include a surface field region of the non-crystalline semiconductor positioned on the first surface of the substrate to be spaced apart from the emitter region, the surface field region containing an impurity of a conductive type equal to a conductive type of the substrate.

The solar cell may further include a second passivation region having a first passivation portion positioned between the substrate and the emitter region and a second passivation portion positioned between the substrate and the surface field region.

Each of the first and second passivation portions may have a thickness of 1 nm to 10 nm.

Each the first and second passivation portions may have a fixed charge.

The fixed charge of the first passivation portion may be opposite to the fixed charge of the second passivation portion.

The first passivation portion may have the fixed charge equal to the conductive type of the substrate, and the second passivation portion may have the fixed charge opposite the conductive type of the substrate.

The fixed charge of each of the first and second passivation portions may have a magnitude of 1×10¹²/cm² to 1×10¹⁵/cm², respectively.

Each of the first and second passivation portions may have a thickness of 3 nm to 20 nm.

The emitter region may be positioned on an incident surface of the substrate.

The first passivation region may be positioned between the emitter region and the substrate.

The first passivation region may have a fixed charge, and a polarity of the fixed charge may be opposite to a conductive type of the substrate.

The solar cell may further include a second passivation region positioned on a surface of the substrate opposite the incident surface of the substrate, and made of an oxide material.

The second passivation region may be made of silicon oxide, aluminum oxide or zinc oxide.

The solar cell may further include a surface field region of the non-crystalline semiconductor positioned on the second passivation region, and the second electrode may be electrically connected to the substrate through the surface field region.

The second passivation region may be a fixed charge, and a polarity of the fixed charge may be opposite to a conductive type of the substrate.

The solar cell may further include a surface field region positioned on the second passivation region and made of the non-crystalline semiconductor, and the second electrode may be electrically connected to the substrate through the surface field region.

### BRIEF DESCRIPTION OF THE DRAWINGS

The accompanying drawings, which are included to provide a further understanding of the invention and are incorporated in and constitute a part of this specification, illustrate example embodiments of the invention and together with the description serve to explain the principles of the invention. In the drawings:

FIGS. 1 and 2 are partial sectional views of solar cells according to example embodiments of the invention, respectively;

FIGS. 3 and 4 are partial sectional views of solar cells according to other example embodiments of the invention, respectively; and

FIGS. 5 and 6 are partial sectional views of solar cells according to yet other example embodiments of the invention, respectively.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to example embodiments of the invention, examples of which are illustrated in the accompanying drawings.

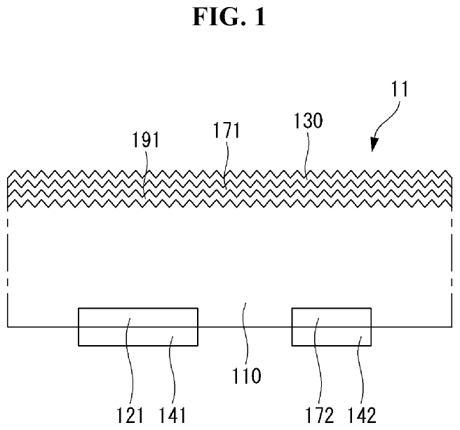

An example of a solar cell of according to an example embodiment of the invention is described in detail with reference to FIG. 1.

FIG. 1 is a partial sectional view of a solar cell according to an example embodiment of the invention.

As shown in FIG. 1, a solar cell 11 according to an example embodiment of the invention includes a substrate 110, a front passivation region 191 positioned on an incident surface (hereinafter, referred to as “a front surface”) of the substrate 110 on which light is incident, a front surface field (FSF) region 171 positioned on the front passivation region 191, an anti-reflection layer 130 positioned on the FSF region 171, a plurality of emitter regions 121 positioned toward a surface (hereinafter, referred to as “a back surface”) of the substrate 110 opposite the front surface of the substrate 110, a plurality of back surface field (BSF) regions 172 that are positioned toward the back surface of the substrate 110 to be separated from the plurality of emitter regions 121, and a plurality of first electrode 141 respectively positioned on the plurality of emitter regions 121, and a plurality of second electrodes 142 respectively positioned on the plurality of BSF regions 172.

The substrate 110 is a semiconductor substrate formed of, for example, first conductive type silicon, such as n-type silicon, though not required. Silicon used in the substrate 110 may be crystalline silicon such as single crystal silicon and polycrystalline silicon. When the substrate 110 is of an n-type, the substrate 110 is doped with impurities of a group V element such as phosphor (P), arsenic (As), and antimony (Sb). Alternatively, the substrate 110 may be of a p-type, and/or be formed of semiconductor materials other than silicon. When the substrate 110 is of the p-type, the substrate 110 is doped with impurities of a group III element such as boron (B), gallium (Ga), and indium (In).

The substrate 110 has an uneven surface, that is, a textured surface obtained by performing a saw damage removing process or a texturing process. The saw damage removing process may be performed on a substantially flat surface of the substrate 110, and the texturing process may be performed on a substantially flat surface of the substrate 110 or a surface of the substrate 110 after the saw damage removing process has been performed. For example, when the substrate 110 is made of polycrystalline silicon, the saw damage removing process may be applied to the substrate 110 to form the uneven surface of the substrate 110, and when the substrate 110 is made of single crystal silicon, the texturing process may be applied to the substrate 110 to form the uneven surface of the substrate 110.

The back surface as well as the front surface of the substrate 110 may have an uneven surface.

The front passivation region 191 on the front surface of the substrate 110 performs a passivation function that converts a defect, for example, dangling bonds existing on the surface of the substrate 110 and around the surface of the substrate 110, into stable bonds to thereby prevent or reduce a recombination and/or a disappearance of charges moving to the front surface of the substrate 110 resulting from the defect. Hence, the front passivation region 191 reduces loss of charges caused by disappearance of the charges due to the defect on or around the surface of the substrate 110.

The front passivation region 191 is made of, for example, an oxide material such as silicon oxide (e.g., SiO_{X}), aluminum oxide (e.g., Al₂O₃), or zinc oxide (e.g., ZnO), etc.

The oxide material for the front passivation region 191 may be formed by a chemical vapor deposition (CVD) process, or a plasma enhanced CVD (PECVD) process.

When the front passivation region 191 is made of silicon oxide (SiO_{X}), the front passivation region 191 may be made of silicon dioxide (SiO₂) formed by a thermal oxidation process.

As compared with a silicon oxide layer formed by another processes other than the thermal oxidation process, when the silicon dioxide layer (SiO₂ layer) is formed by the thermal oxidation process, the uniformity of the silicon dioxide layer increases and the silicon dioxide layer has good quality and step coverage.

Since a formation thickness of the silicon dioxide layer is varied based on a process temperature and a process time, the silicon dioxide layer having a desired thickness is easily obtained by controlling the process temperature and the process time.

When the front passivation region 191 is formed by aluminum oxide or zinc oxide, the front passivation region 191 may be formed by an atomic layer deposition method.

In general, when a layer is formed using the chemical vapor deposition method or a physical vapor deposition method, various reaction materials are simultaneously injected into a process chamber to form the layer. However, in the atomic layer deposition method, one reaction material (an element) at a time of various reaction materials for forming a layer is supplied in a process chamber and form an atomic layer (i.e., an atomic monolayer). Thereby, the atomic layer deposition method is a technique using a chemical adsorption and desorption action of each atomic monolayer by a surface action that occurs due to each reaction material separately supplied in the process chamber.

The atomic layer deposition method includes a process of sequentially supplying the respective reaction materials (reaction gases) into the process chamber and a process of exhausting the reaction materials that are not adsorbed into the atomic monolayer. In addition, each reaction material forms a monomolecular layer on a surface of a substrate, so that a layer in the atomic layer deposition method is formed by a self limiting reaction, to have good step coverage. Furthermore, the atomic layer deposition method enables adjusting a thickness of a layer and to thereby form the layer having a very thin thickness by controlling the number of processes.

Thus, when the front passivation region 191 made of silicon dioxide, aluminum oxide, or zinc oxide is formed by the thermal oxidation method or the atomic layer deposition method, the uniformity and the quality of the front passivation region 191 increase. Thereby, the passivation function of the front passivation region 191 is further improved. Further, the atomic layer deposition method is performed at a temperature (e.g., about 500° C. or less) that is a temperature less than the chemical vapor deposition method, and thereby the deterioration of the substrate 110 is reduced.

In a solar cell according to a comparative example, a front passivation region is made of amorphous silicon (a-Si).

However, since amorphous silicon has a high resistance, an amorphous silicon layer functioning as the front passivation region has a thin thickness such as about 2 nm to 3 nm for decreasing a serial resistance of the solar cell. Thus, it is difficult to uniformly form the amorphous silicon layer on a surface of a substrate regardless of a position of the surface of the substrate, and thereby the amorphous silicon layer has low uniformity, as compared with the front passivation region 191 of the oxide material according to this example embodiment of the invention. In particular, when the substrate has an uneven surface that is not substantially flat, the uniformity of the amorphous silicon layer (i.e., the front passivation region of the comparative example) further decreases. Thereby, in the comparative example, since there exists portions of the substrate, on which the front passivation region of amorphous silicon is not positioned, the passivation function by the front passivation region is not performed on such portions of the substrate, to decrease the passivation effect.

Further, since an amorphous silicon layer is easily crystallized at a temperature of about 200° C. or greater, the passivation function of the front passivation region of amorphous silicon is largely reduced by a crystallization phenomenon (or crystallization) of the amorphous silicon.

As described above, since the thickness of the amorphous silicon layer positioned on the substrate is very thin to compensate for the high resistance, the amorphous silicon layer should be formed quickly over a short time. Thus, it is very difficult to stably and uniformly form the amorphous silicon layer having the thickness of about 2 nm to 3 nm on the substrate, and the process reproduction (or consistent production) of the amorphous silicon layer decreases.

However, when the front passivation region 191 of this example embodiment is made of the oxide material, the uniformity and the quality of the front passivation region 191 are improved and reaction of the oxide material is larger than that of the amorphous silicon. Thus, the passivation effect of the front passivation region 191 of the example increases to improve an efficiency of the solar cell 11.

In addition, since the oxide material does not easily crystallize at a high temperature (e.g., about 500° C.), variance in the characteristics of the front passivation region 191 made of the oxide material does not occur, and the passivation effect of the front passivation region 191 does not decrease.

Further, the front passivation region 191 having a thin thickness is easily and more accurately formed by using the thermal oxidation method and the atomic layer deposition method, and thereby a manufacturing process of the solar cell 11 becomes easier and the process reproduction of the front passivation region 191 increases.

In the example, the front passivation region 191 of the oxide material may have a thickness of approximately 1 nm to 10 nm.

When the thickness of the front passivation region 191 is equal to or greater than approximately 1 nm, the passivation function may be well performed because the uniformity of the front passivation region 191 formed on the substrate 110 increases. When the thickness of the front passivation region 191 is equal to or less than approximately 10 nm, an amount of light absorbed in the front passivation region 191 is reduced. Hence, an amount of light incident in the substrate 110 may increase.

The FSF region 171 positioned on the front passivation region 191 is an impurity region that is more heavily doped with impurities of the same conductive type (e.g., an n-type) as the substrate 110 than the substrate 110.

The FSF region 171 may be made of amorphous silicon.

The FSF region 171 prevent or reduce the movement of desired charges (e.g., holes) to the front surface of the substrate 110 by a potential barrier resulting from a difference between impurity concentrations of the substrate 110 and the FSF region 171, such that a front surface field function is performed at the front surface of the substrate 110. Thus, a front surface field effect by the FSF region 171 is obtained, so that the holes moving to the front surface of the substrate 110 are turned back to the back surface of the substrate 110 by the potential barrier. Hence, a loss amount of charges by a recombination and/or a disappearance of the electrons and the holes at and around the front surface of the substrate 110 is reduced and an output amount of charges to an external device increases.

The anti-reflection layer 130 on the FSF region 171 reduces a reflectance of light incident on the solar cell 11 and increases selectivity of a predetermined wavelength band of the light, thereby increasing the efficiency of the solar cell 11.

The anti-reflection layer 130 may be formed of silicon oxide (SiO_{X}) and/or silicon nitride (SiN_{X}).

Further, the anti-reflection layer 130 may be formed using a transparent metal oxide formed of at least one selected from the group consisting of indium tin oxide (ITO), tin (Sn)-based oxide (for example, SnO₂), zinc (Zn)-based oxide (for example, ZnO, ZnO:Al, ZnO:B, and AZO), and a combination thereof. Other oxides or materials may be used.

The transparency of the transparent metal oxide is greater than the transparency of silicon oxide (SiO_{X}) or/and silicon nitride (SiN_{X}). Thus, when the anti-reflection layer 130 is formed of the transparent metal oxide, an amount of light incident inside the substrate 110 further increases. Hence, the efficiency of the solar cell 11 is further improved.

In this example embodiment, the anti-reflection layer 130 has a single-layered structure, but the anti-reflection layer 130 may have a multi-layered structure such as a double-layered structure in other example embodiments. The anti-reflection layer 130 may be omitted, if desired.

The plurality of emitter regions 121 extend parallel to one another in the back surface of the substrate 110 in a predetermined direction to be separated from one another.

Each emitter region 121 is an impurity area of a second conductive type (for example, a p-type) opposite a conductive type of the substrate 110. Thus, the plurality of emitter regions 121 and the substrate 110 form a p-n junction.

By a built-in potential difference due to the p-n junction of the substrate 110 and the plurality of emitter regions 121, a plurality of electrons and a plurality of holes produced by light incident on the substrate 110 move to the n-type semiconductor and the p-type semiconductor, respectively. Thus, when the substrate 110 is of the n-type and the emitter regions 121 are of the p-type, the holes move to the emitter regions 121 and the electrons move to the back surface of the substrate 110.

Because the substrate 110 and the emitter regions 121 form the p-n junction, the emitter regions 121 may be of the n-type when the substrate 110 is of the p-type unlike the example embodiment described above. In this instance, the electrons move to the emitter regions 121, and the holes move to the back surface of the substrate 110.

When the plurality of emitter regions 121 are of the p-type, the emitter regions 121 may be doped with impurities of a group III element into the back surface of the substrate 110. On the contrary, when the emitter regions 121 are of the n-type, the emitter regions 121 may be doped with impurities of a group V element into the back surface of the substrate 110.

Each of the plurality of BSF regions 172 is an impurity region that is more heavily doped with impurities of the same conductive type as the substrate 110 than the substrate 110. For example, each BSF region 172 may be an n⁺-type region.

The plurality of BSF regions 172 are positioned in the back surface of the substrate 110 to be separated from the emitter regions 121, and extend parallel to the emitter regions 121.

As shown in FIG. 1, the emitter region 121 and the BSF region 172 are alternately positioned in the back surface of the substrate 110.

The BSF regions 172, similar to the FSF region 171, prevent or reduce the movement of holes to the BSF regions 172 used as a moving path of electrons by a potential barrier resulting from a difference between impurity concentrations of the substrate 110 and the BSF regions 172. Further, the BSF regions 172 facilitate the movement of charges (for example, electrons) to the BSF regions 172. Thus, the BSF regions 172 reduce a loss amount of charges by a recombination and/or a disappearance of electrons and holes in or around the BSF regions 172 and accelerate the movement of electrons to the BSF regions 172, thereby increasing an amount of electrons moving to the BSF regions 172.

As shown in FIG. 1, a width of each emitter region 121 is different from a width of each BSF region 172. For example, the width of the emitter region 121 is greater than the width of the BSF region 172. However, in an alternative example embodiment, the width of each emitter region 121 is equal to or less than the width of each BSF region 172.

When the width of the emitter region 121 is greater than that of the BSF region 172, an area of the p-n junction increases, and thereby an amount of the electrons and holes generated in the area of the p-n junction increases and the collection of holes having mobility less than that of electrons is facilitated.

When the width of the BSF region 172 is greater than that of the emitter region 121, a surface area of the substrate 110 which is covered with the BSF regions 172 increases to more improve a back surface field effect obtained by the BSF regions 172.

The plurality of first electrodes 141 on the plurality of emitter regions 121 extend along the emitter regions 121 and are electrically and physically connected to the emitter regions 121

Each first electrode 141 collects charges (for example, holes) moving to the corresponding emitter region 121.

The plurality of second electrodes 142 on the plurality of BSF regions 172 extend along the BSF regions 172 and are electrically and physically connected to the BSF regions 172.

Each second electrode 142 collects charges (for example, electrons) moving to the corresponding BSF region 172.

In FIG. 1, the first and second electrodes 141 and 142 have the same planar shape or sheet shape as the emitter regions 121 and the BSF regions 172 underlying the first and second electrodes 141 and 142. However, they may have different planar shapes in other example embodiments. As a contact area between the emitter regions 121 and the BSF regions 172 and the respective first and second electrodes 141 and 142 increases, a contact resistance therebetween decreases. Hence, a charge transfer efficiency for the first and second electrodes 141 and 142 increases. However, when the planar shape of the first and second electrodes 141 and 142 is smaller than that of the emitter regions 121 and the BSF regions 172 underlying the first and second electrodes 141 and 142, the manufacturing cost of the first and second electrodes 141 and 142 is reduced.

The plurality of first and second electrodes 141 and 142 may be formed of at least one conductive material selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used. As described above, because the plurality of first and second electrodes 141 and 142 may be formed of a metal material, the plurality of first and second electrodes 141 and 142 reflect light passing through the substrate 110 onto the substrate 110.

The solar cell 11 having the above-described structure is a solar cell in which the plurality of first and second electrodes 141 and 142 are positioned into the back surface of the substrate 110, on which light is not incident. An operation of the solar cell 11 is described below.

When light is irradiated onto the solar cell 11, sequentially passes through the anti-reflection layer 130, the FSF region 171, and the front passivation region 191, and is incident on the substrate 110, a plurality of electron-hole pairs are generated in the substrate 110 by light energy based on the incident light. In this instance, because the front surface of the substrate 110 is the uneven surface, a reflectance of light at the front surface of the substrate 110 is reduced, and thereby the efficiency of the solar cell 11 is improved. In addition, because a reflection loss of the light incident on the substrate 110 is reduced by the anti-reflection layer 130, an amount of light incident on the substrate 110 further increases.

The holes move to the p-type emitter regions 121 and the electrons move to the n-type BSF regions 172 by the p-n junction of the substrate 110 and the emitter regions 121. The holes moving to the p-type emitter regions 121 are collected by the first electrodes 141, and the electrons moving to the n-type BSF regions 172 are collected by the second electrodes 142. When the first electrodes 141 and the second electrodes 142 are connected to each other using electric wires, current flows therein to thereby enable use of the current for electric power.

In this example embodiment, since the front passivation region 191 is made of the oxide material such as silicon oxide (SiO_{X}), aluminum oxide (Al₂O₃), or zinc oxide (ZnO), of which the quality and the uniformity are good, the passivation effect by the front passivation region 191 is further improved, to increase the efficiency of the solar cell 11.

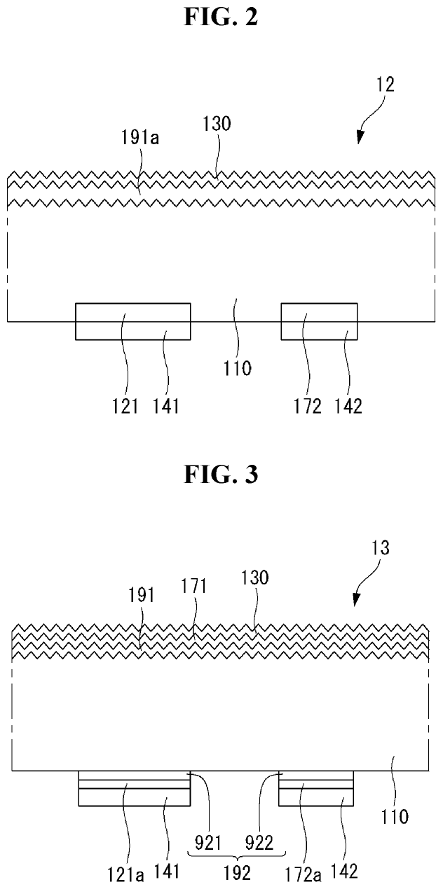

Referring to FIG. 2, another example of the solar cell according to the example embodiment of the invention is described.

FIG. 2 is a partial sectional view of another example of a solar cell according to an example embodiment of the invention.

As compared with FIG. 1, the elements performing the same operations are indicated using the same reference numerals, and the detailed description thereof is omitted.

Except that a FSF region is not positioned on a front surface (that is, an incident surface) of the substrate 110, a solar cell 12 shown in FIG. 2 has the same structure as that of the solar cell 11 of FIG. 1.

Thereby, in the solar cell 12 of this example embodiment, a front passivation region 191a and an anti-reflection layer 130 are sequentially positioned on the front surface of the substrate 110.

The front passivation region 191a that is made of an oxide material may have a fixed charge Q_{F} of a positive polarity (+) or a negative polarity (−) in accordance with a kind of the oxide material.

In this example embodiment, in forming the front passivation region 191a using silicon oxide, aluminum oxide or zinc oxide, a ratio of process gases supplied into a process chamber is controlled to form the oxide layer, for example, the front passivation region 191a, having a desired polarity (that is, a positive polarity or a negative polarity).

In this example embodiment, when the substrate 110 is of an n-type, the front passivation region 191a has a fixed charge (Q_{F}) of a positive polarity (+), and when the substrate 110 is of a p-type, the front passivation region 191a has a fixed charge (Q_{F}) of a negative polarity (−). In this instance, the front passivation region 191a has the fixed charge (Q_{F}) larger than that of the conductivity type of the substrate 110. For example, a material having a fixed charge of a positive polarity (+) may be silicon oxide (SiO_{X}) and a material having a fixed charge of a negative polarity (−) may be aluminum oxide (Al₂O₃).

Thus, when the substrate 110 is of an n-type, the fixed charge of the front passivation region 191a is a positive polarity (+) which is the same as a polarity of minority carriers (i.e., holes) of the substrate 110. Thereby, the holes moving toward the front surface of the substrate 110 is thrust toward the back surface of the substrate 110 by the positive polarity (+) of the front passivation region 191a. Similarly, when the substrate 110 is of a p-type, the fixed charge of the front passivation region 191a is a negative polarity (−) which is the same as a polarity of minority carriers (i.e., electrons) of the substrate 110. Thereby, the electrons moving toward the front surface of the substrate 110 is thrust toward the back surface of the substrate 110 by the negative polarity (−) of the front passivation region 191a.

Thus, desired charges (i.e., electrons or holes) are moved to the back surface of the substrate 110, on which the first or second electrodes 141 or 142 are positioned, which output the electrons or the holes.

As a magnitude of the fixed charge of the front passivation region 191a increases, a movement control effect of the charges using the fixed charge of the front passivation region 191a become large. For example, the fixed charge of the front passivation region 191a may have a magnitude of approximately 1×10¹²/cm² to 1×10¹⁵/cm². The magnitude of the fixed charge may be controlled by varying a composition ratio of the oxide material.

When the magnitude of the fixed charge is equal to or greater than about 1×10¹²/cm², the movement control of the charges is more easily and effectively performed. When the magnitude of the fixed charge is equal to or less than about 1×10¹⁵/cm², a characteristic variation of the front passivation region 191a is prevented or reduced, and the formation of the front passivation region 191a is more easily performed.

Thereby, as already described with reference to FIG. 1, the front passivation region 191a performs the passivation function, and further prevents or reduces the movement of undesired charges to the front surface of the substrate 110 using the polarity of the fixed charge of the front passivation region 191a. Thus, the front passivation region 191a has the similar function to the FSF region 171, and thereby the solar cell 12 of this example embodiment may omit a FSF region. Accordingly, since the FSF region is omitted, manufacturing time and cost for the solar cell 12 are reduced.

In this example embodiment, the fixed charge of the front passivation region 191a has a magnitude of a degree capable of preventing or reducing movements of undesired charges. Thus, the front passivation region 191a has a thickness greater than that of the front passivation region 191 of FIG. 1. For example, the front passivation region 191a may have a thickness of approximately 3 nm to 20 nm.

When the thickness of the front passivation region 191a is equal to or greater than approximately 3 nm, the front passivation region 191a stably generates the fixed charge of a desired polarity having a sufficient magnitude and uniformly applied to the back surface of the substrate 110 to efficiently perform the passivation function. When the thickness of the front passivation region 191a is equal to or less than approximately 20 nm, an amount of light absorbed in the front passivation region 191a is reduced. Hence, an amount of light incident in the substrate 110 may increase.

As described with reference to FIG. 1, since the front passivation region 191a is made of an oxide material, the quality and the uniformity of the front passivation region 191a are improved, the crystallization phenomenon of the front passivation region 191a at a high temperature is prevented to increase the passivation effect of the front passivation region 191a, and the thickness control of the front passivation region 191a is eased.

In an alternative example embodiment, as shown in FIG. 2, when the front passivation region 191a has the fixed charge controlling the movement of the desired charge, the solar cell 12 of the example may further have a front surface field region such as the front surface field region 171 of FIG. 1. In this instance, the front surface field region 171 is positioned between the front passivation region 191a and the anti-reflection layer 130. Thereby, the front passivation function by the front surface field region 171 is additionally performed, an amount of charges that disappear is further reduced, to thereby increase an amount of charges outputted through the first or second electrodes 141 or 142.

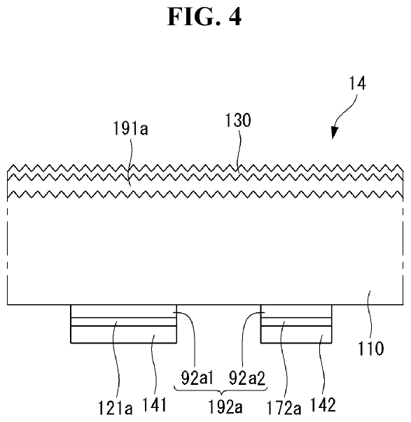

Next, with reference to FIGS. 3 and 4, solar cells 13 and 14 of other example embodiments of the invention are described.

As compared with FIGS. 1 and 2, the elements performing the same operations are indicated using the same reference numerals, and the detailed description thereof is omitted.

The solar cells 13 and 14 shown in FIGS. 3 and 4 include a plurality of emitter regions 121a and a plurality of BSF regions 172a, each which are positioned on a back surface of a substrate 110, respectively. The plurality of emitter regions 121a and the plurality of BSF regions 172a positioned on the same surface are separated from each other. However, in this example embodiment, the plurality of the emitter regions 121a and the plurality of BSF regions 172a form a heterojunction with the substrate 110, unlike the solar cells 11 and 12 shown in FIGS. 1 and 2. Thus, the substrate 110 of the solar cells 13 and 14 is made of a crystalline semiconductor such as single crystal silicon or polycrystalline silicon, but the plurality of emitter regions 121a and the plurality of BSF regions 172a of the solar cells 13 and 14 are made of a non-crystalline semiconductor such as amorphous silicon.

First, the solar cell 13 of a heterojunction structure shown in FIG. 3 is described.

The solar cell 13 has the similar structure to that of the solar cell 11 of FIG. 1.

The solar cell 13 of this example includes a substrate 110 of the crystalline semiconductor, a front passivation region 191, a FSF region 171 and an anti-reflection layer 130 sequentially positioned on a front surface of the substrate 110, the plurality of emitter regions 121a positioned on the back surface of the substrate 110 and extending parallel to each other, and the plurality of BSF regions 172a spaced apart from the plurality of emitter regions 121 on the back surface of the substrate 110 and extending parallel to each other, a plurality of first electrodes 141 positioned on the plurality of emitter regions 121a, and a plurality of second electrodes 142 positioned on the plurality of BSF regions 172a.

Unlike the example embodiment of FIG. 1, the plurality of emitter regions 121a of the solar cell 13 are formed using the PECVD method, etc., and made of the non-crystalline semiconductor such as amorphous silicon. However, like the solar cell 11 shown in FIG. 1, the plurality of emitter regions 121a contain impurities of a conductive type opposite a conductive type of the substrate 110, and thereby form a p-n junction with the substrate 110.

Unlike the solar cell 11 of FIG. 1, the plurality of BSF regions 172a are formed using the PECVD method, etc., and made of the non-crystalline semiconductor such as amorphous silicon. However, the plurality of BSF regions 172a contains impurities of the same conductive type as the substrate 110 and the impurities are more heavily doped into the BSF regions 172a than the substrate 110, as is described in FIG. 1.

Thus, the BSF regions 172a, in the same manner as the BSF region 172 of FIG. 1, performs the back surface field function using a potential barrier generated by a difference between impurity concentrations of the substrate 110 and the BSF regions 172a. Accordingly, the BSF regions 172a reduce a loss amount of charges by a recombination and/or a disappearance of electrons and holes that occur in or around the back surface of the substrate 110, and accelerate the movement of desired charges (e.g., electrons) to the BSF regions 172a, thereby increasing an amount of charges moving to the second electrodes 142.

The front passivation region 191 on the front surface of the substrate 110 is made of an oxide material such as silicon oxide (e.g., SiO_{X}), aluminum oxide (e.g., Al₂O₃), or zinc oxide (e.g., ZnO), as described with reference to FIG. 1.

However, the solar cell 13 of this example embodiment further includes a back passivation region 192. The back passivation region 192 includes a plurality of first back passivation portions 921 positioned between the back surface of the substrate 110 and the plurality of emitter regions 121a and a plurality of second back passivation portions 922 positioned between the back surface of the substrate 110 and the plurality of BSF regions 172a.

Like the front passivation region 191, the plurality of first and second back passivation portions 921 and 922 are made of an oxide material such as silicon oxide (e.g., SiO_{X}), aluminum oxide (e.g., Al₂O₃), or zinc oxide (e.g., ZnO). Other oxides or materials may be used.

The oxide layer for the back passivation region 192 may be formed by the CVD method or the PECVD method, etc. In particular, when the back passivation region 192 is made of silicon oxide, the back passivation region 192 may be formed by a thermal oxidation method, and when the back passivation region 192 is aluminum oxide (e.g., Al₂O₃) or zinc oxide (e.g., ZnO), the back passivation region 192 may be formed by the atomic layer deposition method.

Like the front passivation region 191, the back passivation region 192 performs the passivation function, to thereby reduce loss charges caused by disappearance of the charges due to the defect on or around the back surface of the substrate 110.

Each of the first back passivation portions 921 and each of the second back passivation portions 922 may have the same thickness as the front passivation region 191. Thereby, each of the first back passivation portions 921 and each of the second back passivation portions 922 may have a thickness of approximately 1 nm to 10 nm. The thicknesses of the first and second back passivation portions 921 and 922 do not prevent the movement of the charges moving to the emitter regions 121a and the back surface field regions 172a positioned on the first and second back passivation portions 921 and 922.

When the thickness of each of the first and second back passivation portions 921 and 922 is equal to or greater than approximately 1 nm, the passivation function may be well performed because the uniformity of the first and second back passivation regions 921 and 922 formed on the substrate 110 increases. When the thickness of each of the first and second back passivation regions 921 and 922 is equal to or less than approximately 10 nm, an amount of light absorbed in the first and second back passivation regions 921 and 922 without the prevention of the charge movement to the emitter regions 121a and the back surface field regions 172a is reduced. Hence, an amount of light incident in the substrate 110 may increase.

As compared with the solar cell 11 of FIG. 1, since a difference of energy band gap Eg between the crystalline silicon substrate 110 and the amorphous silicon regions 121a and 172a due to the heterojunction increases, the solar cell 13 has an open voltage Voc larger than that of the solar cell 11 of FIG. 1. Thus, an efficiency of the solar cell 13 is further improved.

In addition, since the passivation regions 191 and 192 are positioned on the back surface as well as the front surface of the substrate 110, the loss of charges by disappearance of the charges due to the defect on or around the front and back surfaces of the substrate 110 is further decreased to improve the efficiency of the solar cell 13.

As compared with a solar cell of a comparative example, which includes a back passivation region of amorphous silicon, the quality and the uniformity of the back passivation region 192 of the solar cell 13 are improved, the crystallization phenomenon of the back passivation region 192 at a high temperature is prevented to increase the passivation effect of the back passivation region 192, and the thickness control of the back passivation region 192 becomes eased.

The solar cell 14 of FIG. 4 has a similar structure to a structure of the solar cell 13 of FIG. 3. However, the solar cell 14 includes the front passivation region 191a shown in FIG. 2 and does not include the FSF region of FIG. 3. Thereby, as described with reference to FIG. 2, the front passivation region 191a is made of an oxide material and performs the passivation function. Furthermore, since the front passivation region 191a has a fixed charge of the opposite polarity [e.g., a positive polarity (+)] to the conductive type of the substrate 110, the front passivation region 191a prevents or reduces the movement of undesired charges to the front surface of the substrate 110 by using the polarity of the fixed charge.

Thereby, since it is possible to omit the FSF region 171, the manufacturing time and cost for the solar cell 14 are reduced, and an efficiency of the solar cell 14 increases because a recombination and/or a disappearance of electrons and holes in or around the front passivation region 191a is reduced.

However, as described with reference to FIG. 2, when the solar cell 14 includes the front passivation region 191a having the fixed charge of a desired polarity, the solar cell 14 may further include a front surface field region 171 between the front passivation region 191a and the anti-reflection layer 130, to further increase the front field effect.

The solar cell of FIG. 4 further includes a back passivation region 192a that includes a plurality of first back passivation portions 92a1 and a plurality of second back passivation portions 92a2 underlying the plurality of emitter regions 121a and the BSF regions 172a, respectively. The first and second back passivation portions 92a1 and 92a2 are also made of an oxide material and have a fixed charge of a desired polarity, respectively.

For example, when the substrate 110 is of an n-type, the plurality of first back passivation portions 92a1 underlying the plurality of emitter regions 121a of a p-type have a fixed charge of a negative polarity (−) and the plurality of second back passivation portions 92a2 underlying the plurality of BSF regions 172a of an n-type have a fixed charge of a positive polarity (+).

By the first back passivation portions 92a1 of the negative polarity (−), electrons of a negative polarity moving to the emitter regions 121a are repulsed, while holes of a positive polarity are attracted to the emitter regions 121a. Thereby, an amount of the holes moving to the first electrodes 141 increases, and an recombination and/or disappearance of the electrons and the holes at the emitter regions 121a decreases, to increases the amount of the holes moving to the first electrodes 141.

Similar to the first back passivation portions 92a1, by the second back passivation portions 92a2 of the positive polarity (+), holes moving to the BSF regions 172a are repulsed to the substrate 110, while holes are attracted to the BSF regions 172a. Thereby, a recombination and/or disappearance of the electrons and the holes at the BSF regions 172a decreases and an amount of the electrons moving to the second electrodes 142 increases.

In an alternative example, when the substrate 110 is of a p-type, the emitter regions 121a and the plurality of BSF regions 172a have the conductive types opposite to those instances where the substrate 110 is of the n-type, respectively. Thus, the fixed charges of the first and second back passivation portions 92a1 and 92a2 are also changed, respectively.

Thereby, when the substrate 110 is of a p-type, the plurality of first back passivation portions 92a1 underlying the plurality of emitter regions 121a have a fixed charge of a positive polarity (+) and the plurality of second back passivation portions 92a2 underlying the plurality of BSF regions 172a have a fixed charge of a negative polarity (−).

Thus, by the first back passivation portions 92a1 of the positive polarity (+), the holes are repulsed to the front surface of the substrate 110, while the electrons are attracted to the emitter regions 121a, and by the first back passivation portions 92a2 of the negative polarity (−), the electrons are repulsed to the front surface of the substrate 110, while the holes are attracted to the back surface field regions 172a. Therefore, an amount of the electrons moving to the emitter regions 121a which collect the electrons and an amount of the holes moving to the back surface field regions 172a which collect the holes increase.

Each of the first and second back passivation portions 92a1 and 92a2 has a thickness greater than that of each of the first and second back passivation portions 921 and 922 of FIG. 3. For example, each of the first and second back passivation portions 92a1 and 92a2 has a thickness of approximately 1 nm to 20 nm.

When the thickness of each of the first and second back passivation portions 92a1 and 92a2 is equal to or greater than approximately 1 nm, the first and second back passivation regions 92a1 and 92a2 stably generate fixed charge of a desired polarity having a sufficient magnitude and uniformly applied to the back surface of the substrate 110 to efficiently perform the passivation function. When the thickness of each of the first and second passivation portions 92a1 and 92a2 is equal to or less than approximately 20 nm, the charges easily move from the first and second back passivation portions 92a1 and 92a2 to the emitter regions 121a and the BSF regions 172a overlaying the first and second back passivation portions 92a1 and 92a2, and an amount of light absorbed in the first and second back passivation region 92a1 and 92a2 is reduced.

Since the front and back passivation regions 191a and 192a positioned on the front and back surfaces of the substrate 110 have fixed charge of a predetermined polarity, respectively, the recombination of electrons and holes at the emitter regions 121a and the BSF regions 172a is prevented or reduced. Thereby, a charge transfer amount from the emitter regions 121a and the BSF regions 172a to the first and second electrodes 141 and 142 increases to improve an efficiency of the solar cell 14.

In an alternative example embodiment, the first and second back passivation regions 921 and 922, and 92a1 and 92a2 may be made of intrinsic amorphous silicon instead of the oxide material. In this instance, the first and second back passivation regions 921 and 922, and 92a1 and 92a2 of intrinsic amorphous silicon are directly positioned on the back surface of the substrate 110 of a crystalline semiconductor.

Thereby, the first and second back passivation regions 921 and 922, and 92a1 and 92a2 of intrinsic amorphous silicon are positioned between the crystalline semiconductor substrate 110 and the emitter regions 121a and BSF regions 172a, and thereby, in forming the emitter regions 121a and the BSF regions 172a on the first and second back passivation regions 921 and 922, the first and second back passivation regions 921 and 922 prevent a crystalline phenomenon of at least one of each emitter region 121a and at least one of each BSF region 172a due to the influence of the crystalline substrate 110. Thereby, the solar cell of the heterojunction structure ensures improvement an efficiency of the solar cell.

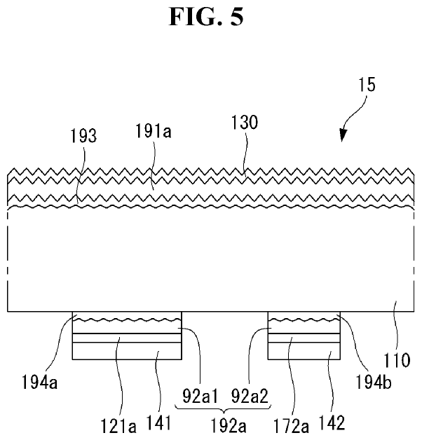

Referring to FIG. 5, a solar cell 15 according to another embedment of the invention is described.

The solar cell 15 of FIG. 5 includes a silicon oxide portion 193 at least between a substrate 110 and a front passivation region 191a.

Further, the solar cell 15 further includes silicon oxide portions 194a and 194b at least between a back surface of the substrate 110 and a plurality of first back passivation regions 92a1 and at least between the back surface of the substrate 110 and a plurality of second back passivation portions 92a1, respectively.

In this instance, the front passivation region 191a, and a back passivation region 192a of the first and second back passivation portions 92a1 and 92a2 may be made of aluminum oxide or zinc oxide, which is formed by the atomic layer deposition method. Other materials may be used for the first and second back passivation portions 92a1 and 92a2.

When oxide material for the passivation regions 191a, 92a1 and 92a2 is formed by the atomic layer deposition method, the silicon oxide portions 193, 194a and 194b may be formed by the combination of silicon contained in the substrate 110 and oxide for the passivation regions 191a, 92a1 and 92a2.

In another example embodiment, at least one of the silicon oxide portion 193 on the front surface of the substrate 110 and the silicon oxide portions 194a and 194 on the back surface of the substrate 110 may be omitted if necessary.

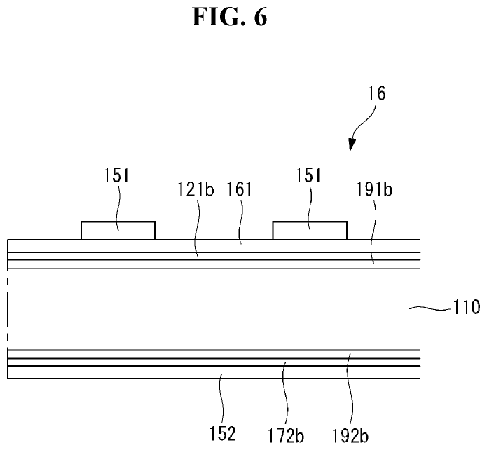

Next, a solar cell according to yet another example embodiment of the invention is described with reference to FIG. 6.

FIG. 6 is a partial sectional view of a solar cell according to yet another example embodiment of the invention.

Similar to the solar cells 13 and 14 of FIGS. 3 and 4, a solar cell 16 of FIG. 6 has a substrate 110 made of a crystalline semiconductor and an emitter region 121b positioned on the substrate 110 and made of a non-crystalline semiconductor. Thereby, the substrate 110 forms a heterojunction with the emitter region 121b, and the solar cell 16 shown in FIG. 6 is a solar cell of a heterojunction structure.

Referring to FIG. 6, the solar cell 16 is described in detail.

The solar cell 16 includes the substrate 110, a front passivation region 191b positioned on a front surface (an incident surface) of the substrate 110, the emitter region 121b positioned on the front passivation region 191b, an auxiliary electrode 161 positioned on the emitter region 121b, a plurality of front electrodes 151 positioned on the auxiliary electrode 161, a back passivation region 192b positioned on a back surface of the substrate 110, a BSF region 172b positioned on the back passivation region 192b, and a back electrode 152 positioned on the BSF region 172b.

As described, since the solar cell 16 has the heterojunction structure like the solar cells 13 and 14 of FIGS. 3 and 4, the substrate 110 is made of crystalline silicon, while the emitter region 121b and the BSF region 172b are made of amorphous silicon. The emitter region 121b and the BSF region 172b contain impurities of a corresponding conductive type, respectively.

In this example embodiment, the emitter region 121b is positioned on the substantially entire front surface of the substrate 110, and the BSF region 172b is positioned on the substantially entire back surface of the substrate 110.

As compared with the emitter regions 121a and the BSF regions 172a of FIGS. 3 and 4, the emitter region 121b and the BSF region 172b of FIG. 6 perform the same functions as the emitter region 121a and the BSF region 172a, except for formation positions and shapes of the emitter region 121b and the BSF region 172b. Thereby, the detailed description of the emitter region 121b and the BSF region 172b is omitted.

Thus, an open voltage of the solar cell 16 by the heterojunction of the substrate 110 and the emitter region 121b increases, to improve an efficiency of the solar cell 16.

As with the passivation regions 191, 191a, 192 and 192a already described above, the front passivation region 191b positioned between the substrate 110 and the emitter region 121b, and the back passivation region 192b positioned between the substrate 110 and the BSF region 172b are made of an oxide material such as silicon oxide, aluminum oxide, or zinc oxide, and perform the passivation function.

Thereby, since the front and back passivation regions 191b and 192b are made of an oxide material, the quality and the uniformity of the front and back passivation regions 191b and 192b are improved, the crystallization of the front and back passivation regions 191b and 192b is made difficult to thereby increase the passivation effect of the front and back passivation regions 191b and 192b, and the thickness control of the front and back passivation regions 191b and 192b is easy.

In this instance, charges (holes and electrons) moving to the front and back surfaces of the substrate 110 should reach the emitter region 121b and the BSF region 172b through the front and back passivation region 191b and 192b, respectively. Thereby, the front and back passivation region 191b and 192b have thicknesses to a degree not influencing the movement of the charges to the emitter region 121b and the BSF region 172b, respectively.

As described with reference to FIGS. 2 and 4, the front and back passivation regions 191b and 192b may have fixed charges of a negative polarity (−) or a positive polarity (+) in accordance with the conductive type of the substrate 110, respectively. In this instance, the movement of undesired charges to the front or back surface of the substrate 110 is prevented or reduced, such that a recombination and/or a disappearance of electrons and holes in or around the front passivation region 191a is reduced to improve the efficiency of the solar cell 16.

The auxiliary electrode 161 is made of a transparent material, which has a low specific resistance and good conductivity. For example, the auxiliary electrode 161 is made of a transparent conductive material such as a transparent conductive oxide (TCO) of ITO (indium tin oxide) or ZnO (zinc oxide), etc.

The plurality of front electrodes 151 are positioned on the auxiliary electrode 161 to be separated from each other and extend in a predetermined direction.

Each of the front electrodes 151 collects charges (for example, holes) passing through the auxiliary electrode 161 and output the charges to an external device.

The back electrode 152 positioned on the BSF region 172b are positioned on the substantially entire back surface of the substrate 110.

The back electrode 152 collects charges (for example, electrons) moving to the BSF region 172b and output the charges to the external device.

The front and back electrodes 151 and 152 may be formed of at least one conductive material selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used.

The auxiliary electrode 161 forms a contact resistance between the emitter region 121b made of amorphous silicon of a high resistance and the plurality of front electrodes 151 of a metal material. Thus, the auxiliary electrode 161 decreases a serial resistance of the solar cell 16 and increases a charge transfer amount from the emitter region 121b to the plurality of front electrodes 151.

In embodiments of the invention, reference to fixed charges includes oxide fixed charges.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell, comprising:
a single crystalline semiconductor substrate;
an emitter region positioned on an incident surface of the substrate, forming a p-n junction with the single crystalline semiconductor substrate;
a first passivation layer positioned on a rear surface of the substrate and made of an oxide material;
a back surface field layer positioned on the first passivation layer and forming a hetero junction with the single crystalline semiconductor substrate;
a first electrode electrically connected to the emitter region; and
a second electrode electrically connected to the single crystalline semiconductor substrate.

2. The solar cell of claim 1, wherein the first passivation layer is 1-10 nm thickness.

3. The solar cell of claim 1, further comprising a second passivation layer positioned on the incident surface of the substrate.

4. The solar cell of claim 3, wherein the second passivation layer is 1-10 nm thickness.

5. The solar cell of claim 3, wherein the second passivation layer is made of silicon oxide, aluminum oxide or zinc oxide.

6. The solar cell of claim 1, wherein the first passivation layer is made of silicon oxide, aluminum oxide or zinc oxide.

7. The solar cell of claim 1, wherein the back surface field layer is made of non-crystalline silicon.

8. The solar cell of claim 1, wherein the emitter region is made of non-crystalline silicon.

9. The solar cell of claim 1, wherein polarity of the emitter region is opposite to the polarity of the substrate.

10. The solar cell of claim 1, wherein polarity of the back surface field layer is equal to the polarity of the substrate.

11. The solar cell of claim 1, wherein the back surface field layer is formed of amorphous silicon.
